(19) United States
(12) Patent Application Publication
(10) Pub. No.: US 2014/0153197 A1
(43) Pub. Date: Jun. 5, 2014

(54) POWER SUPPLY DEVICE

(71) Applicant: HON HAI PRECISION INDUSTRY CO., LTD., New Taipei (TW)

(72) Inventor: CHIEN-CHUNG YEN, New Taipei (TW)

(73) Assignee: HON HAI PRECISION INDUSTRY CO., LTD., New Taipei (TW)

(21) Appl. No.: 14/083,471

(22) Filed: Nov. 19, 2013

(30) Foreign Application Priority Data
Dec. 3, 2012 (TW) 101145252

(51) Int. Cl. H05K 7/00

(52) U.S. Cl. CPC H05K 7/00
USPC 361/729

(57) ABSTRACT

A power supply device includes a first power conversion unit and a second power conversion unit. The first power conversion unit includes a first interface and a second interface. The second power conversion unit includes a third interface and a fourth interface. The third interface is configured to detachably connect to the second interface. When the third interface is connected to the second interface, the first power conversion unit and the second power conversion unit are electrically connected with each other. When third interface is disconnected from the second interface, the first power conversion unit and the second power conversion unit are detached from each other.

### BACKGROUND

1. Technical Field

Embodiments of the present disclosure relate to a power supply device.

2. Description of Related Art

Power supply device may have one or more voltage/current conversion units, such as an alternating current (AC) to direct current (DC) unit, a DC to DC unit, and a power factor correction (PFC) unit, to provide required voltage/current to external electrical devices. These units may be integrated and connect with each other in the power supply device. However, when one of these units is damaged or malfunctioning, the power supply device will not work, which may cause inconvenience. Therefore, there is room for improvement in the art.

### BRIEF DESCRIPTION OF THE DRAWINGS

FIG. 1 illustrates a power supply device having a first power conversion unit and a second power conversion unit.

FIG. 2 illustrates a schematic diagram of a third interface of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

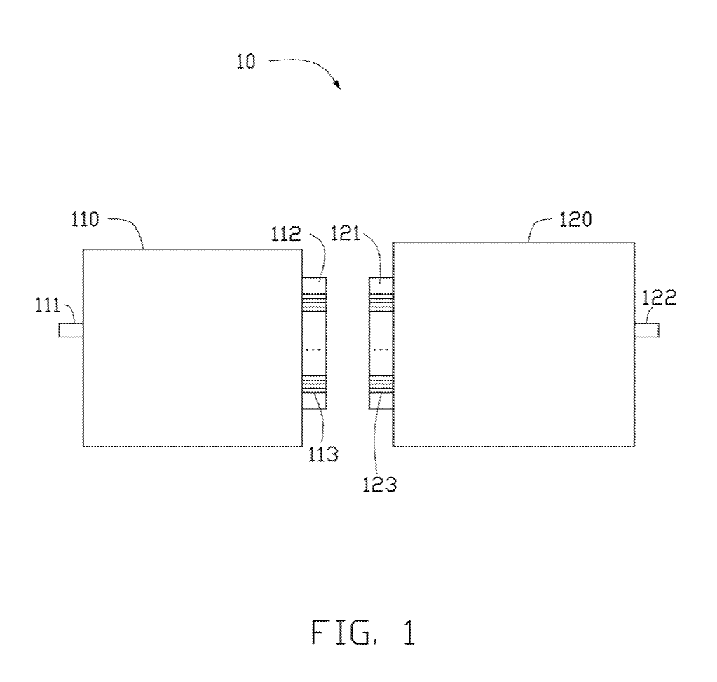

FIG. 1 shows a power supply device 10 according to an exemplary embodiment. In the embodiment, the power supply device 10 is configured to convert alternating current (AC) current into direct current (DC), to power external electrical devices using the direct current.

The power supply device 10 includes a first power conversion unit 110 and a second power conversion unit 120. The first power conversion unit 110 includes a first interface 111 and a second interface 112. The first interface 111 is configured to connect to an external AC power source to receive AC power from the external AC power source. The first power conversion unit 110 converts the received AC power into a first DC power, and outputs the first DC power via the second interface 112. The AC power received from the external AC power source may have a voltage of 220V or 110V. The first DC power may have a voltage of 24V or 48V. The second interface 112 includes an edge connector (e.g., golden finger) having a plurality of conductive pins 113.

The second power conversion unit 120 is detachably connected to the first power conversion unit 110. The second power conversion unit 120 includes a third interface 121 and a fourth interface 122. The third interface 121 is configured to detachably connect to the second interface 112 of the first power conversion unit 110. When the third interface 121 is connected to the second interface 112, the second power conversion unit 120 receives the first DC power output from the second interface 112 of the first conversion unit 110. The second power conversion unit 120 further converts the received first DC power into at least one second DC power, and outputs the at least one DC power via the fourth interface 122 to power the external electrical devices using the at least one second DC power. The second DC power may have a voltage of 3V, 5V, 12V, or 24V, for example. When the third interface 121 is disconnected from the second interface 112, the first power conversion unit 110 and the second power conversion unit 120 are detached from each other. Thus, when one of the first power conversion unit 110 and the second power conversion unit 120 is damaged or malfunctions, the damaged or malfunctioning unit can be replaced by detaching the first power conversion unit 110 and the second power conversion unit 120 from each other.

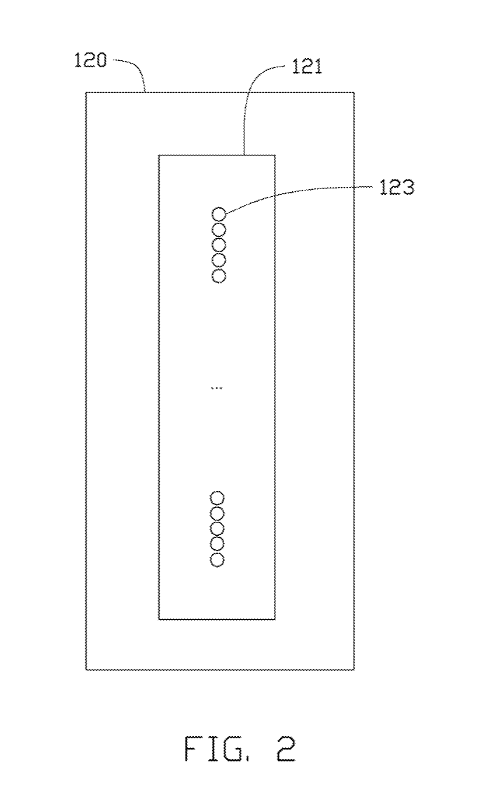

FIG. 2 shows that in one illustrated embodiment, the third interface 121 may include a plurality of hole-shaped conductive ports 123. The plurality of conductive pins 113 of the second interface 112 can be plugged into the hole-shaped conductive ports 123 to connect the third interface 121 to the second interface 112, thereby establishing an electrical connection between the first power conversion unit 110 and the second power conversion unit 120. When one of the first power conversion unit 110 and the second power conversion unit 120 needs to be replaced, the first power conversion unit 110 and the second power conversion unit 120 can be detached from each other by pulling the plurality of conductive pins 113 of the second interface 112 out of the hole-shaped conductive ports 123 of the third interface 121.

In the embodiment, the first power conversion unit 110 may further include a power factor correction (PFC) circuit (not shown) to provide a PFC function for the power supply device 10. The second power conversion unit 120 may be a DC to DC boost circuit, a DC to DC buck circuit, or a circuit having both a DC to DC boost circuit and a DC to DC buck circuit.

As described above, the first power conversion unit 110 and the second power conversion unit 120 can be detachably connected with each other. When one of the first power conversion unit 110 and the second power conversion unit 120 is damaged or malfunctioned, the damaged or malfunctioned unit can be easily replaced.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A power supply device, comprising;
a first power conversion unit comprising a first interface and a second interface, the first interface configured to connect to an external alternating current (AC) power source to receive AC power from the external AC power source, the first power conversion unit converting the received AC power into a first direct current (DC) power and outputting the first DC power via the second interface; and
a second power conversion unit detachably connected to the first power conversion unit comprising a third interface and a fourth interface, the third interface configured to connect to the second interface, the second power conversion unit converting the first DC power into at least one second DC power and outputting the at least one second DC power via the fourth interface to power external electrical devices using the at least one second DC power;
wherein when the third interface is connected to the second interface, the first power conversion unit and the second power conversion unit are electrically connected with each other; when third interface is disconnected from the second interface, the first power conversion unit and the second power conversion unit are detached from each other.

2. The power supply device according to claim 1, wherein the second interface comprises an edge connector having a plurality of conductive pins.

3. The power supply device according to claim 2, wherein the third interface comprises a plurality of hole-shaped conductive ports, and the plurality of conductive pins of the second interface are plugged into the hole-shaped conductive ports to connect the third interface to the second interface, thereby establishing an electrical connection between the first power conversion unit and the second power conversion unit.

4. The power supply device according to claim 1, wherein the first power conversion unit further comprises a power factor correction (PFC) circuit to provide a PFC function for the power supply device.

5. The power supply device according to claim 1, wherein the second power conversion unit is a DC to DC boost circuit.

6. The power supply device according to claim 1, wherein the second power conversion unit is a DC to DC buck circuit.

7. The power supply device according to claim 1, wherein the second power conversion unit is a circuit having a DC to DC boost circuit and a DC to DC buck circuit.

8. The power supply device according to claim 1, wherein the AC power received from the external AC power source has a voltage of 220V or 110V.

9. The power supply device according to claim 1, wherein the first DC power has a voltage of 24V or 48V.

10. The power supply device according to claim 1, wherein the second DC power has a voltage of 3V, 5V, 12V, or 24V.
